(19) United States
(12) Patent Application Publication
(10) Pub. No.: US 2003/0150562 A1
(43) Pub. Date: Aug. 14, 2003

(54) Apparatus and method to control the uniformity of plasma by reducing radial loss

(76) Inventor: Bill H. Quon, Brea, CA (US)

Correspondence Address: PILLSBURY WINTHROP, LLP, P.O. BOX 10500, MCLEAN, VA, 22102, US

(21) Appl. No.: 10/378,691

(22) Filed: Mar. 5, 2003

Related U.S. Application Data
(63) Continuation of application No. PCT/US01/42111, filed on Sep. 12, 2001.
(60) Provisional application No. 60/231,878, filed on Sep. 12, 2000.

(51) Int. Cl. C23F 1/00; C03C 15/00; H01L 21/461; C23C 16/00

(52) U.S. Cl. 156/345.47; 118/723 E; 427/569; 216/67; 438/710; 438/788

(57) ABSTRACT

A capacitively coupled plasma reactor composed of: a reactor chamber enclosing a plasma region; upper and lower main plasma generating electrodes for generating a processing plasma in a central portion of the plasma region by transmitting electrical power from a power source to the central portion while a gas is present in the plasma region; and a magnetic mirror including at least one set of magnets for maintaining a boundary layer plasma in a boundary portion of the plasma region around the processing plasma. A capacitively coupled plasma reactor composed of: a reactor chamber enclosing a plasma region; upper and lower plasma generating electrodes for generating a processing plasma in the plasma region by transmitting electrical power from a power source to the plasma region while a gas is present in the plasma region; and power supplies for applying a VHF drive voltage to the upper plasma generating electrode and RF bias voltages at a lower frequency than the VHF drive voltage to the upper and lower plasma generating electrodes.

This is a Continuation of International Application No. PCT/US01/42111, which was filed on Sep. 12, 2001 and claims the benefit of U.S. Provisional Application No. 60/231,878, which was filed Sep. 12, 2000, the contents of which are incorporated herein by reference.

### BACKGROUND OF THE INVENTION

The present invention relates to methods and apparatus for generating a plasma in a plasma chamber, the plasma being used for performing various industrial and scientific processes including etching and layer deposition on a semiconductor wafer.

Plasma generating systems are currently widely used in a number of manufacturing procedures such as etching and layer deposition on wafers as part of integrated circuit manufacturing processes. The basic components of such a system are a plasma chamber enclosing a processing region in which a plasma will be formed, a plasma electrode, usually at the top of the chamber, for delivering RF electrical power into the chamber in order to initiate and sustain the plasma, and a wafer chuck, usually at the bottom of the chamber, to hold a wafer on which integrated circuits will be formed. Such a system further necessarily includes associated devices for delivering plasma-forming gas and processing gas to the chamber and pumping gas out of the chamber in order to maintain both a desired gas pressure and a desired gas composition in the chamber. One of the key desiderata in plasma reactor design is to increase plasma density while maintaining plasma uniformity.

There are two major sources of plasma non-uniformity in parallel plate plasma reactors, or RF capacitively coupled plasma (CCP) systems, currently used in the industry: radial plasma losses; and highly localized harmonic contents.

In a CCP parallel plate plasma reactor, both the plasma electrode and the chuck, which can also be considered to be an electrode, are capacitively coupled to RF power sources, and self-bias potentials are developed on these electrodes. In existing systems, the plasma is typically associated with a halo plasma, which is a scattered plasma surrounding the discharge gap existing everywhere inside the chamber. An electric field having a large gradient in the radial direction can be developed through the halo plasma in contact with the chamber wall. Since the plasma potential is time dependent in nature and the plasma always contacts the chamber wall in these CCP reactors, there is always a time dependent radial electric field gradient in the plasma in these CCP reactors. This radial electric field gradient is associated with radial diffusion near the plasma edge. The diffusive loss generates a plasma density profile in which the plasma density is higher in the center and lower near the edge of the chamber. This diffusive radial plasma density profile is one major source of plasma non-uniformity due to radial plasma losses.

As concerns plasma non-uniformity caused by highly localized harmonic contents, if the driven frequency on the plasma electrode of a parallel plate reactor is increased, the energy contained at harmonic frequencies of the RF electric field increases rapidly. Interference among these harmonic contents always occurs inside the plasma chamber. The contribution to the total RF electric field due to the harmonic interference causes the total RF electric field on the surface of the electrodes to become non-uniform. The non-uniformity in plasma density could be much greater than the total electric field non-uniformity because high frequency power is much more efficient in creating high plasma densities. The high harmonic frequencies create additional plasma density, but they contribute even more strongly to the plasma non-uniformity. So the harmonic contents and their interference with each other is another major source of plasma non-uniformity.

For the semiconductor industry, if a system with non-uniform plasma is used for semiconductor wafer processing, the non-uniform plasma discharge will produce non-uniform deposition or etching on the surface of the semiconductor wafer. Thus, the control of the uniformity of the plasma directly affects the quality of the resulting integrated semiconductor chips.

The trend in the semiconductor equipment industry is toward reactor sources for processing ever larger wafers, current efforts being devoted to progressing from plasma reactor sources capable of processing wafers with a diameter of 200 mm to those capable of processing wafers with a diameter of 300 mm. Since local field non-uniformity increases as a substantial function of the source dimension relative to wavelength, it is expected that greater non-uniformity will be found in 300-mm systems than in equivalent 200-mm systems. Thus, control of the uniformity of the plasma becomes critical for larger systems.

In VHF CCP systems of the type currently used in the industry, both the upper electrode and the chuck are capacitively coupled to the RF power source or to respective power sources. The processing plasma in such systems makes contact with the chamber wall through the halo plasma existing in the chamber surrounding the discharge gap. Lack of control of the halo plasma makes it difficult to control the time dependent plasma potential. There is also a significant time-dependent radial electric field gradient existing near the outer edge of the processing plasma. This radial electric field gradient increases radial plasma loss, introduces charging damage near the wafer edge, and possibly causes sputtering on the chamber wall.

### BRIEF SUMMARY OF THE INVENTION

The present invention provides improved plasma density uniformity in CCP systems.

The invention is implemented by a capacitively coupled plasma reactor comprising: a reactor chamber enclosing a plasma region; upper and lower main plasma generating electrodes for generating a processing plasma in a central portion of the plasma region by transmitting electrical power from a power source to the central portion while a gas is present in the plasma region; and means including at least one set of magnets for maintaining a boundary layer plasma in a boundary portion of the plasma region around the processing plasma.

The invention is further implemented by a capacitively coupled plasma reactor comprising: a reactor chamber enclosing a plasma region; upper and lower plasma generating electrodes for generating a processing plasma in a central portion of the plasma region by transmitting electrical power from a power source to the central portion while a gas is present in the plasma region; and means for applying a VHF drive voltage to the upper plasma generating electrode and RF bias voltages at a lower frequency than the VHF drive voltage to the upper and lower plasma generating electrodes.

The invention is not limited to systems which employ VHF drive voltages, and at least some aspects of the invention apply to a wide range of RF frequencies used for semiconductor processing. However, the current industry trend is toward the use of VHF drive voltages for parallel plate, CCP process reactors. Although edge non-uniformity due to radial losses can be observed in all such reactors, the plasma non-uniformity associated with harmonics of the fundamental frequency can be greatly exacerbated when the fundamental drive voltage frequency is in the VHF range.

### BRIEF DESCRIPTION OF THE SEVERAL VIEWS OF THE DRAWING

FIGS. 1, 2A, 2B and 2C are simplified cross-sectional pictorial views of four embodiments of apparatus according to the invention.

FIGS. 3A, and 3B are plasma potential waveform diagrams illustrating one aspect of the invention.

FIG. 4 is a block circuit diagram illustrating another aspect of the invention.

FIGS. 5A, 5B, 6A and 6B are electrode voltage and plasma potential waveform diagrams illustrating a further aspect of the invention.

FIG. 7 is a diagram of a RF power supply circuit for supplying power to electrodes of a reactor according to the invention.

FIG. 8 is a pictorial illustration of the electron and ion gradient-B drifts in a circular ring cusp magnetic field.

### DETAILED DESCRIPTION OF THE INVENTION

This invention relates to an apparatus and a method for improving the radial uniformity of the plasma density profile in a plasma chamber by reducing the radial electric field gradient and radial losses. Apparatus according to this invention is a new type of capacitively coupled plasma reactor, and has been termed a Capacitively Coupled Double Plasma (CCDP) reactor.

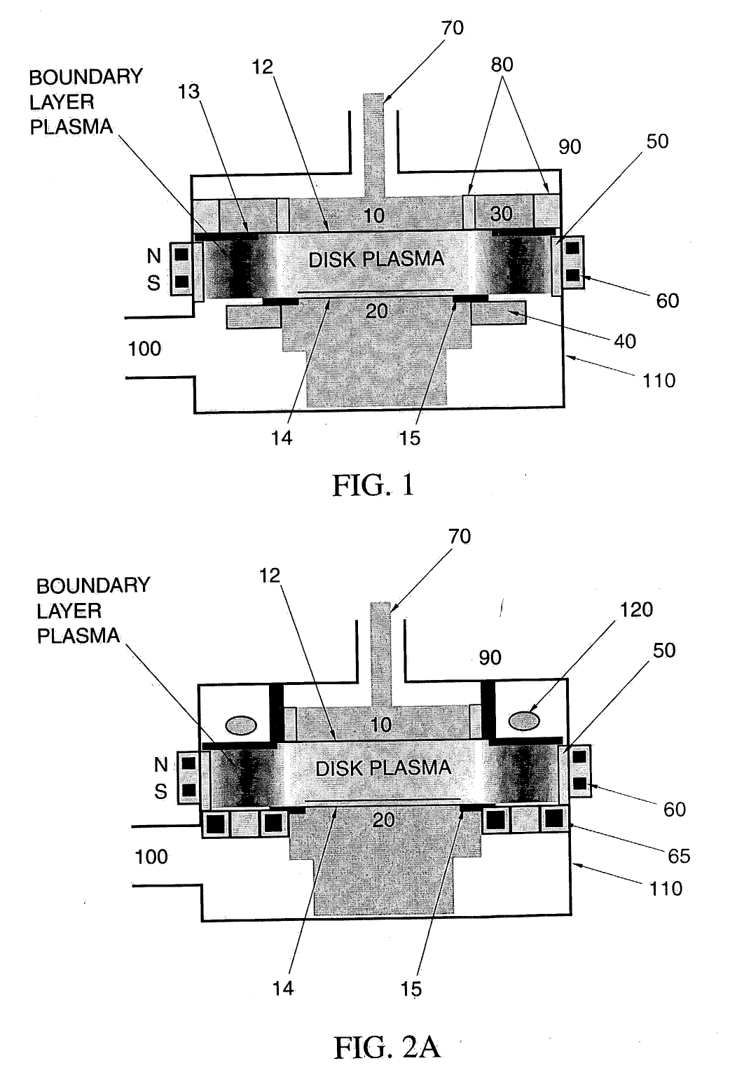

A simplified cross-sectional pictorial view of one embodiment of an apparatus according to the invention is shown in FIG. 1. The basic elements of the illustrated apparatus include: an upper disk electrode 10 within which a gas delivery element 12, commonly termed a showerhead, is disposed for injecting process gas into a plasma region where an etching or deposition operation is to be performed; a quartz shield ring 13; a wafer 14 to be processed; a chuck focus ring 15; a lower disk electrode 20 constituted by a chuck for supporting a wafer to be processed; an upper ring electrode 30; a lower ring electrode 40; a cylindrical electrode 50 surrounding electrodes 30 and 40; one or more rings of permanent magnets 60; an RF feed line 70; a ceramic washer 80; a top cover 90; and a vacuum chamber having a wall 110 of cylindrical shape provided with a pumping port 100. The interior of the vacuum chamber encloses the plasma region.

In the embodiment shown in FIG. 1, there are two vertically superposed rings of permanent magnets 60. Each permanent magnet has a radially extending polarization axis, with the north poles of the permanent magnets in one ring pointing inwardly and those of the other ring pointing outwardly. Thus, in this embodiment, permanent magnets 60 form an annular magnetic field having magnetic field lines that extend generally vertically along arcuate paths between the two rings of magnets. In an alternate embodiment, any of the permanent magnets can be replaced with an electromagnet.

Cylindrical electrode 50 is surrounded by magnets 60. Cylindrical electrode 50 and magnets 60 act together as a magnetic mirror wall for reflecting plasma away from wall 110. The rings of permanent magnets 60 have a field strength and spacing to create a magnetic field that is sufficiently strong close to the surface of cylindrical electrode 50 to reflect the plasma in a manner to have a substantial confining effect and to keep the plasma density relatively uniform in the radial direction to a short distance from electrode 50. By arranging magnets 60 in the manner described above, plasma near the magnetic mirror wall will circulate in a closed surface, and plasma loss and charge separation along the cusp axes will be reduced greatly.

The electrons and ions in the plasma near the magnetic mirror wall will be subject to several drift motions. First, there will be magnetic field gradient drift V_{∇B} and magnetic field line curvature drift V_{Rc}, viz.

V_{∇B}=±½v_{⊥}ρ(BX∇B)/B²

V_{Rc}=±½v_{//}ρ(R_{c}X∇B)/R_{c}²B²

where the + sign corresponds to electron and the − sign corresponds to ion, v_{⊥} and v_{//} are the perpendicular and parallel thermal velocities, and ρ is the corresponding gyroradius of the particle specie, respectively. In these drifts, electrons and ions are drifting in opposite directions, but are both drifting in directions perpendicular to the magnetic field lines and the direction of the magnetic field gradient or the direction of field line curvature. For the circular line cusp configuration used in embodiments of the present invention, the electrons and ions are drifting azimuthally, but in directions opposite to each other, in closed orbits as illustrated in FIG. 8.

There is another drift due to the electric field in the plasma,

V_{EXB}=(EXB)/B²

which is always perpendicular to the magnetic field lines and the electric field E that is present in the plasma. In this case, the ions and electrons are drifting in the same direction.

Since the magnetic field near the magnet wall is decreasing as one moves away from the magnets, the gradient drift and the curvature drift are both always present there. It is important to ensure that these drifts are in closed orbits so that no charge separation is present anywhere in the plasma. Otherwise, the particle drift motions can generate charge-separation, leading to a large-scale space-charge field E. The plasma can be moved collectively by the EXB drift, resulting in a large non-uniformity in plasma density.

In the embodiment shown in FIG. 1, the processing plasma is generated between electrodes 10 and 20 and the boundary layer plasma is formed between ring electrodes 30 and 40 and is confined radially by magnetic mirror 50, 60.

In the operation of the embodiment shown in FIG. 1, VHF RF power at 60 MHz or higher may be applied to upper disk electrode 10 via a DC blocking capacitor while RF power at a lower frequency, for example of the order of 2 MHz, is also applied to upper disk electrode 10 to create a DC self-bias on electrode 10. Lower frequency RF power at, for example, 2 MHz is also applied to lower disk electrode 20, upper ring electrode 30 and lower ring electrode 40 to create DC self-biases on these electrodes. A conventional power splitter with individual amplitude and phase control for each output (not shown) may be used to deliver individually controlled lower frequency RF power to each of the four electrodes. By applying the same low frequency bias voltages to the upper ring and disk electrodes and to the lower ring electrode and disk electrodes, controllability of the ion energy and the spatial potential uniformity of the processing plasma are improved. Cylindrical electrode 50 can be grounded, or biased with DC or low frequency RF voltage at 2 MHz for plasma potential control.

During the plasma process, the CCDP process reactor creates two plasma discharges: one in the center between upper and lower disk electrodes 10 and 20 as a processing plasma; and the other surrounding the center processing plasma between upper and lower ring electrodes 30 and 40 as a boundary layer ring plasma. The center processing plasma is mainly generated by the high frequency power at 60 MHz or higher supplied to the upper disk electrode. The lower frequency RF power at 2 MHz applied to the upper and lower disk electrodes generates the self-bias voltage on these electrodes. The center processing plasma usually has a relatively high density, for example in the range of 1 to 3×10¹¹ cm⁻³ and the boundary layer ring plasma can have a lower density, for example <1×10¹¹ cm⁻³. The boundary layer plasma is predominantly generated by the low frequency RF power at 2 MHz supplied to the upper and lower ring electrodes with confinement of that plasma by the magnetic mirror wall to maintain the desired boundary layer plasma density and profile. The magnetic mirror wall, consisting of cylindrical electrode 50 and one or more sets of permanent magnets 60, reflects the plasma from cylindrical wall 110 and maintains the boundary layer ring plasma.

In general, depending on the excitation frequency range, different physics phenomena occur in the plasma. At lower frequencies, secondary electrons generated by ion bombardment are responsible for sustaining the plasma. Higher applied voltages are necessary for maintaining the plasma density as well as the etching or deposition rate. At higher frequencies, e.g. higher than 13.56 MHz, high plasma density can be generated with lower applied voltages so that high processing rates can be realized with low bias and little damage. The current trend is to apply a high frequency, e.g., 60 MHz, to one electrode, typically the upper electrode, to create the processing plasma, and to apply a lower frequency, e.g., 2 MHz, bias voltage to the chuck to control ion energy thereabove. The low frequency bias voltages applied on the electrodes will strongly affect the time-dependent plasma potential.

The boundary layer plasma is created essentially to influence the center processing plasma. When the boundary layer plasma is biased by the same low frequency RF as the center processing plasma, the boundary layer plasma will be at about the same time-dependent plasma potential. As a result, radial, ambipolar diffusion from the center processing plasma will be minimized.

Electrodes having a variety of shapes or other devices can be used to create a boundary layer plasma having the desired shape. One preferred embodiment in the current structure is a set of ring electrodes, as described above with reference to FIG. 1. The ring electrodes are used mainly to ensure that an axially symmetrical flat plasma potential profile is maintained in the entire center processing plasma.

The apparatus shown in FIG. 1 can be operated in several modes. For example, upper ring electrode 30 can be floated or RF biased and cylindrical electrode can be floating or grounded. An electrode is electrically floating when it is electrically isolated from both ground potential, as by using capacitive coupling, and a bias potential. The electrode then achieves a potential, commonly referred to as the floating potential, such that the net ion and electron current to the electrode is zero.

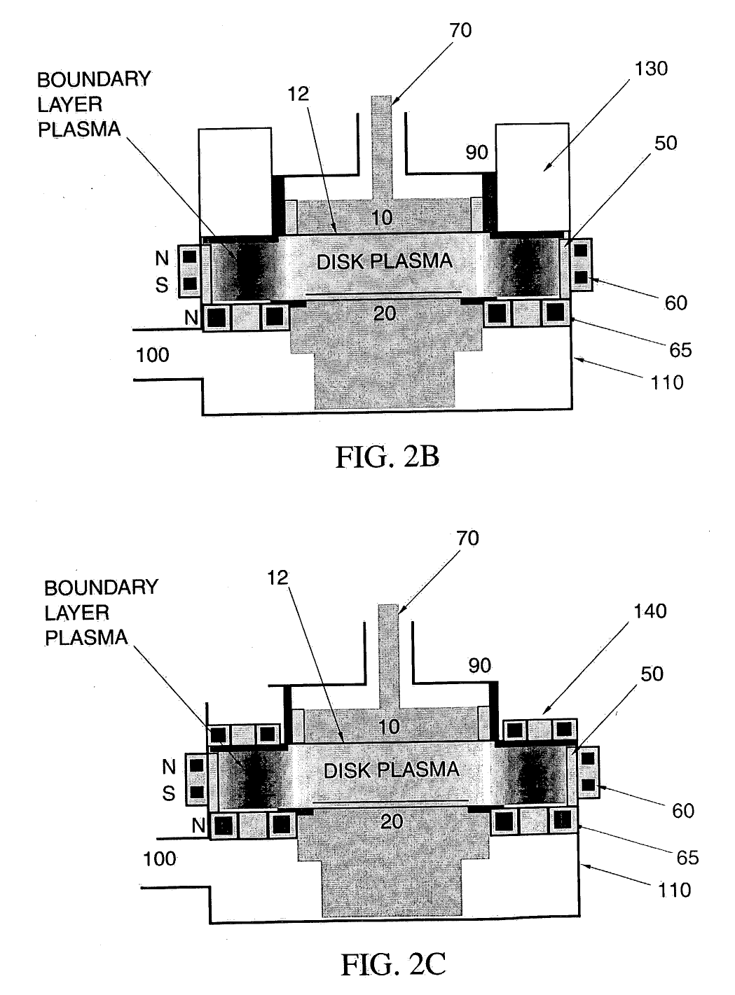

The boundary layer plasma can also be created by other means than the ring electrodes, as described below with reference to FIGS. 2A, 2B and 2C, in which components identical to those shown in FIG. 1 are given the same reference numerals.

The second embodiment of apparatus according to the invention shown in FIG. 2A differs from that of FIG. 1 in that ring electrodes 30 and 40 are replaced by an electrostatically shielded radio frequency (ESRF) loop antenna, or single turn coil, 120 which is inductively coupled to the peripheral portion of the plasma region to form the boundary layer plasma region. The magnetic mirror wall is made less lossy and more inclusive by adding two rings of permanent magnets 65 adjacent the lower part of the peripheral portion of the plasma region, essentially in the position occupied by ring electrode 40 in the embodiment of FIG. 1. Magnets 65 all have a vertically oriented polarization axis and are arranged in an inner ring of magnets whose north poles face downwardly and an outer ring of magnets whose north poles face upwardly. The inner and outer rings are centered on a common horizontal plane. In this configuration, the cylindrical magnetic mirror wall is extended radially inwardly to cover the region immediately outside disk electrodes 10 and 20.

The third embodiment shown in FIG. 2B differs from the embodiment of FIG. 2A only by replacement of coil 120 with a slotted waveguide 130 connected to a microwave power source (not shown) to generate an electron cyclotron resonance (ECR) plasma. The microwave power source can be a conventional device generating electrical power at a frequency of, for example, 2.45 GHz.

The fourth embodiment shown in FIG. 2C differs from that of FIG. 2B only in that slotted waveguide 130 and its connected microwave power source are replaced by two further rings of permanent magnets 140 disposed above the region containing the boundary layer plasma. These magnets will be oriented in the same manner as magnets 65. Thus, in this embodiment, the boundary layer plasma is enclosed on three sides by permanent magnets which cooperate with cylindrical electrode 50 to form the magnetic mirror.

In all of the above-described embodiments, the magnetic mirror is used distinctively for reflecting the plasma. In addition to confining the plasma in cylindrical geometry and minimizing radial plasma loss, this mirror will further decouple the chamber from the plasma potential.

The magnetic mirror wall can also be made in shapes other than those illustrated. For example, the mirror can be constituted by an array of magnets lying on a curved annular surface, like a portion of a torus.

In a CCDP process reactor according to the invention, only the center processing plasma is used for processing a workpiece, or wafer. The boundary layer ring plasma itself is not used for processing, but is provided mainly to make the center processing plasma more uniform and more controllable. The existence of the boundary layer ring plasma minimizes any potential difference in the electric field between the center and the edge of the processing plasma, and helps maintain the center processing plasma more uniform.

Control of the time dependent plasma potential in the processing plasma is also of importance. In the configuration proposed in this invention, the center processing plasma is insulated completely from the system wall by the boundary layer ring plasma. In a capacitively coupled plasma discharge, electron current flows to any electrode that is biased at a potential more positive than the plasma potential, and ion current flows to any electrode that is biased at a potential more negative than the plasma potential. In a steady state, or repeated CW, operation, the time average electron current must equal the time average ion current. There are two factors that determine the balance of these currents: (1) electrons have much higher mobility than ions; and (2) the electron current increases exponentially as the potential difference between the plasma potential and the electrode voltage increases. On a capacitively coupled electrode, a self-DC bias voltage is developed so that the most positive bias voltage on the electrode becomes about equal to the peak plasma potential. Thus in a multiple electrode system, the processing plasma potential will follow the most positive instantaneous potential of the upper or lower disk electrodes. This makes it possible to apply the top and bottom bias voltages in modes such that those voltages are in phase or out of phase with one another. In these modes of operation, the ion energy can be controlled to about ˜10 eV, determined by the accuracy of the amplitudes and phases of the top and bottom bias voltages, if such low ion energy is desirable for the process applications.

By applying the same low frequency bias voltages to the upper and lower disk electrodes, the controllability of the ion energy is improved dramatically. The spatial potential uniformity of the center processing plasma will also be improved by applying the same bias voltage also to the upper and lower ring electrodes of the embodiment of FIG. 1.

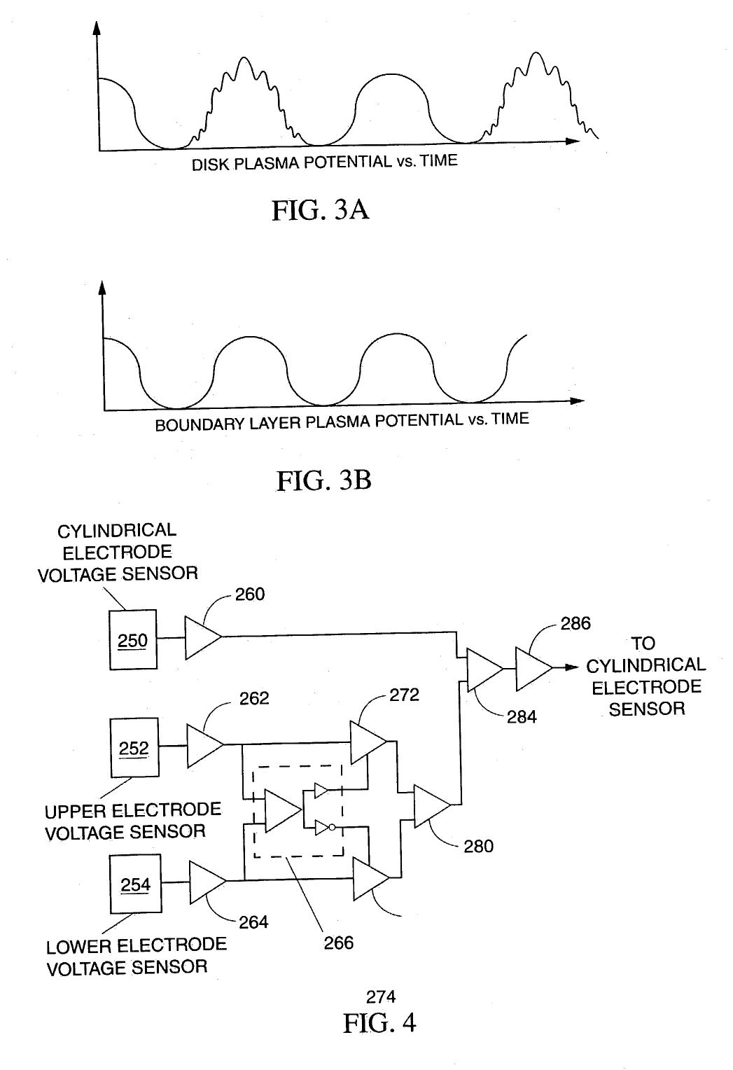

FIGS. 3A and 3B show the electrode voltage and the resulting time dependent plasma potentials in the center processing plasma and the boundary layer ring plasma, respectively, when a VHF drive voltage at a frequency of, for example, 60 MHz, is applied to upper disk electrode 10 and a RF bias voltage at, for example, 2 MHz, is applied to all of the electrodes 10, 20, 30 and 40. The bias voltages applied to the electrodes can be in phase or out of phase with one another. When the bias voltages applied to associated upper and lower electrodes are in phase, plasma potential control can be improved. However, a phase difference of 80 degrees between electrodes 10 and 20 or electrodes 30 and 40 can lead to a reduction of the transfer of power from the fundamental frequency to the harmonic frequencies. An optimal phase difference exists for each specific case.

Because the same low frequency bias voltage drives the lower disk and ring electrodes, the low frequency time dependent plasma potentials of the two plasmas are identical. This will greatly reduce radial ambipolar diffusion of the plasma, even though a high frequency drive voltage is being applied to upper disk electrode 10. The magnetic field acting on the boundary layer plasma must be strong enough to magnetize the electrons to reflect the plasma electrons magnetically. “Magnetized” electrons are electrons moving in a magnetic field that preferably move in helical motions about magnetic field lines and, in general, are constrained to move along field lines rather than across them. Typically, collisional processes are required to diffuse electrons across magnetic field lines. For the case presented herein, the desired field strength for magnetized electrons is approximately 200 Gauss, below which the degree of “magnetization” is lessened. There will be a surface layer rich in ions near the magnet mirror, which gives rise to a positive local potential to reflect the plasma ions electrostatically. The effective leak width on the ring cusp, for the case of ambipolar diffusion, is given by the so-called hybrid gyroradius: ρ=(ρₑρᵢ)^{1/2}; where ρₑ and ρᵢ are the electron gyroradius and ion gyroradius, respectively.

In accordance with a further feature of the present invention, cylindrical electrode 50 is maintained at a potential substantially equal to the plasma potential which varies at the low RF frequency. One embodiment of a circuit for achieving such control is shown in FIG. 4 in which voltages at the low RF frequency on cylindrical electrode 50, upper electrode 10 and lower electrode 20 are monitored by respective voltage sensors 250, 252 and 254. The output voltages from sensors 250, 252 and 254 are amplified to appropriate levels by respective amplifiers 260, 262 and 264. The output voltages from amplifiers 260, 262 and 264 are applied to a comparator circuit 266 composed of a differential amplifier, a buffer and an inverter, the function of which will be described below.

The output of amplifier 262 is further supplied to the input of a gate 272, while the output of amplifier 264 is supplied to the input of a gate 274. The opening and closing of gates 272 and 274 is controlled by respective outputs of comparator 266 in such a manner that if the output from amplifier 262 is more positive, gate 272 is opened and if the output of amplifier 264 is more positive, gate 274 is opened. The outputs of gates 272 and 274 are connected to a combining element 280. Thus, the output signal from amplifier 260 is representative of the voltage on cylindrical electrode 50, while the output of combining circuit 280 is representative of the higher of the voltages on upper electrode 10 and lower electrode 20, which voltage corresponds to the potential of the processing plasma.

The output voltages from amplifier 260 and combining circuit 280 are supplied to respective inputs of a differential amplifier 284 and the output, which is representative of the difference between the voltages of the output of amplifier 260 and the output of combining unit 280, is supplied to the input of a power amplifier 286 which drives electrode 50. Thus, with this circuit arrangement, the output voltage from power amplifier 286 will act to maintain the voltage on cylindrical electrode 50 equal to the higher value of the voltages on electrodes 10 and 20.

In the circuit of FIG. 4, use will be made of circuit components which have a sufficiently rapid response to allow the voltage on cylindrical electrode 50 to follow the low RF component of the potential of the processing plasma. As a result, low frequency current drawn into the surface of the chamber wall will be minimized.

This control of the voltage on cylindrical electrode 50, contributes significantly to suppression of the radial electric field gradient in the ring plasma, thereby further suppressing any radial electric field gradient in the processing plasma.

The combination of a magnetic mirror wall with a cylindrical electrode and feedback circuit according to the present invention offers the advantage of reflecting electrons as well as ions. The reflection of plasma from the magnetic mirror wall controls the radial profile of the plasma and reduces radial losses of the plasma. The result is a greater processing plasma uniformity and increased plasma density. The magnetic mirror wall according to the invention also helps to insulate the outer chamber wall from the plasma. The outer chamber wall does not draw any current and is no longer subjected to sputtering damage.

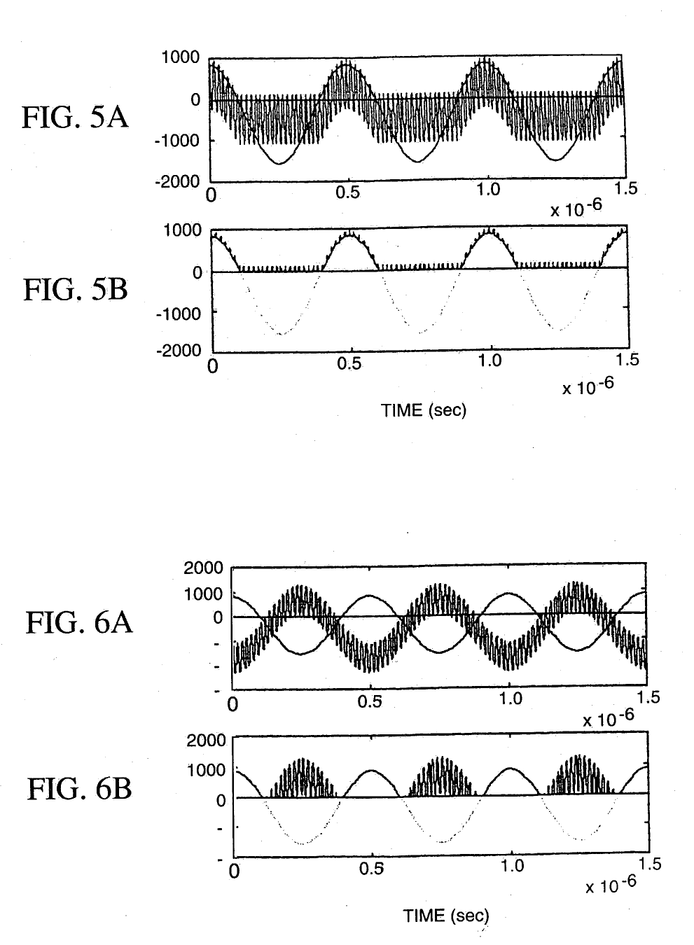

As described earlier herein, a reactor according to the invention can be operated with a VHF drive voltage applied to the upper disk electrode and a low RF bias voltage applied to both the upper and lower disk electrodes. According to a further feature of the invention, such an operating scheme can be used to reduce the harmonic content of the electric field generated in the plasma. This feature will be described with reference to FIGS. 5A, 5B, 6A and 6B.

When a high frequency voltage is applied to upper disk electrode 10 and a low frequency voltage is applied to lower disk electrode, or chuck, 20, as is done in prior art systems, these voltages are rectified in the plasma because the plasma potential is always greater than or equal to zero volts (ground potential) and equal to the more positive one of the potentials on the two electrodes.

FIG. 5A shows the voltages applied to both electrodes, where, according to the prior art, only a high frequency (VHF) voltage is applied to upper disk electrode 10 and only a low frequency RF voltage is applied to chuck 20. FIG. 5B shows the resultant plasma potential, which is always the more positive of the two electrode voltages. Here, high frequency harmonics are generated continuously, i.e., throughout the entire cycle of the low frequency wave. Therefore, the electric field in the plasma has a substantial harmonic content.

In the contrast, FIGS. 6A and 6B show electrode voltages and plasma potential, respectively, when both a low RF frequency voltage and a high frequency voltage are applied to upper disk electrode 10, and only the low RF frequency modulation voltage is applied to chuck 20. The low frequency RF voltages applied to upper disk electrode 10 and chuck 20 are equal in magnitude but out of phase by 180°. FIG. 6B shows the resultant plasma potential, where the high frequency harmonics are generated only over one-half of each cycle of the low frequency RF wave, thereby reducing the harmonic content of the electric field in the plasma. In general, it has been found that application of a RF bias to upper disk electrode 10 which is 180° out of phase from the RF bias applied to chuck 20 produces desirable effects, i.e. reduced harmonics and improved uniformity. However, there may be a different phase difference which is optimal, as described above. The level of generation of harmonics or transfer of power to the harmonic frequencies can dramatically affect the process uniformity to a greater extent than the mean process rate, or plasma density.

The feature illustrated in FIGS. 6A and 6B can be utilized advantageously in a CCP reactor of conventional construction, i.e., one not equipped to produce or sustain a ring plasma and with or without a cylindrical electrode 50 and control circuit of the type shown in FIG. 4.

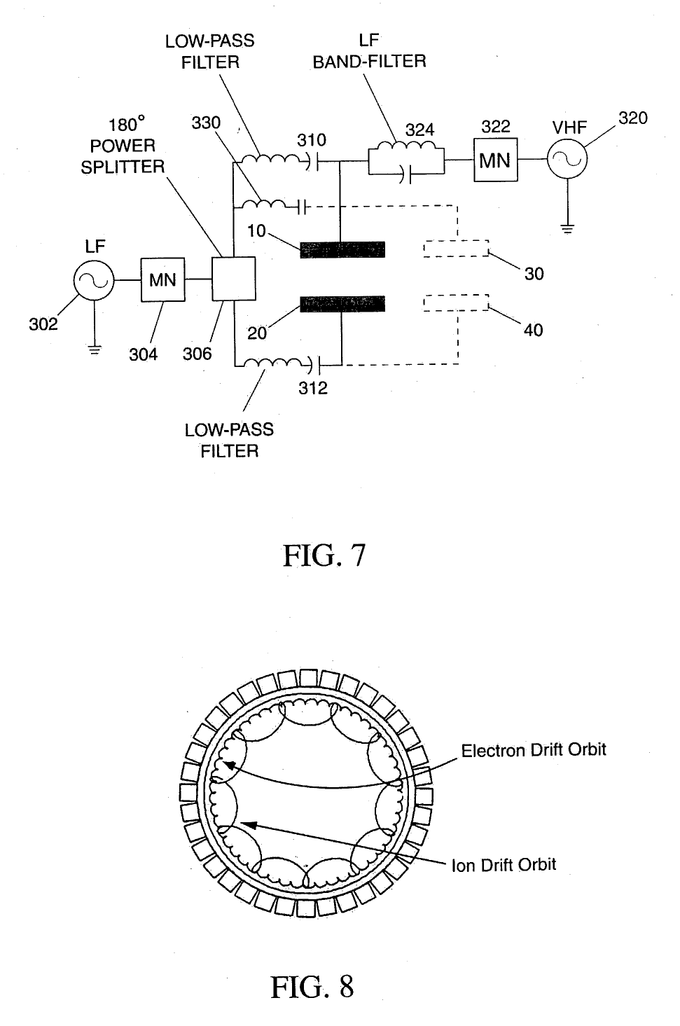

FIG. 7 shows a diagram of a circuit that may be operated to produce the electrode voltages and plasma potential illustrated in FIGS. 6A and 6B. The associated reactor may be identical to that shown in FIG. 1 with electrodes 30 and 40 removed. The circuit includes a RF power source 302 producing an output voltage of, for example, 2 MHz, which is, relatively speaking, a low frequency. This output voltage is supplied via an impedance match network 304 to a power splitter 306 which splits the power from source 302 into two branches while shifting the voltage in one branch by 180° relative to the voltage in the other branch. The power may be split in any desired ratio. The power in each branch is supplied via a respective lowpass filter 310, 312, which passes power at 2 MHz, to a respective one of electrodes 10 and 20. Higher frequency VHF power at, for example, 60 MHz is produced by a VHF power source 320 and supplied via an impedance match network 322 and a low frequency band-reject filter 324 which blocks power at 2 MHz to electrode 10.

The circuit of FIG. 7 may also supply electrodes 10 and 20 of the other illustrated embodiments and, with the addition of low-pass filter 330 and the connections shown in broken lines in FIG. 7, may also supply electrodes 30 and 40 of the embodiment of FIG. 1.

Power may also be distributed to the various electrodes by circuit arrangements of the type disclosed in U.S. Provisional Application No. 60/192,508, filed by Parsons on Mar. 28, 2000, the entirety of which is incorporated herein by reference. Such arrangements allow RF power to be delivered to multiple electrodes while enabling the adjustment of power and phase difference between the RF signal on separate electrodes.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. A capacitively coupled plasma reactor comprising:
a) a reactor chamber enclosing a plasma region;
b) upper and lower main plasma generating electrodes for generating a processing plasma in a central portion of the plasma region by transmitting electrical power from a power source to the central portion while a gas is present in the plasma region; and
c) means including at least one set of magnets for maintaining a boundary layer plasma in a boundary portion of the plasma region around the processing plasma.

2. The reactor of claim 1 wherein the boundary layer plasma is located outside of a region delimited by said main plasma generating electrodes.

3. The reactor of claim 2 wherein said at least one set of magnets comprise a first annular array of permanent magnets.

4. The reactor of claim 3 wherein the annular array of magnets surrounds the boundary portion.

5. The reactor of claim 4 wherein said at least one set of magnets comprise a second annular array of magnets below the boundary portion.

6. The reactor of claim 5 wherein said at least one set of magnets comprise a third annular array of magnets above the boundary portion.

7. The reactor of claim 5 wherein said means for maintaining comprise a plasma generator above the boundary portion.

8. The reactor of claim 7 wherein said plasma generator is an inductively coupled plasma generator or a microwave plasma generator.

9. The reactor of claim 3 wherein said means for maintaining comprise upper and lower ring electrodes surrounding said main plasma generating electrodes and disposed respectively above and below the boundary portion.

10. The reactor of claim 9 further comprising means for applying a VHF drive voltage to said upper main plasma generating electrode and RF bias voltages at a lower frequency than the VHF drive voltage to the upper and lower main plasma generating electrodes and the upper and lower ring electrodes.

11. The reactor of claim 10 wherein the RF bias voltages applied to said upper and lower main plasma generating electrode are out of phase with one another.

12. The reactor of claim 1 further comprising a cylindrical electrode surrounding the boundary portion for providing a voltage that maintains a uniform radial electric field intensity in the boundary layer plasma.

13. The reactor of claim 12 further comprising a control circuit connected between said main plasma generating electrodes and said cylindrical electrode for maintaining a voltage on said cylindrical electrode that is substantially equal to the potential of the processing plasma.

14. The reactor of claim 13 wherein said control circuit maintains the voltage on said cylindrical electrode at a value corresponding to the more positive one of the voltages on said main plasma generating electrodes.

15. The reactor of claim 12 wherein the cylindrical electrode is maintained at a DC bias voltage.

16. A capacitively coupled plasma reactor comprising:
a) a reactor chamber enclosing a plasma region;
b) upper and lower plasma generating electrodes for generating a processing plasma in the plasma region by transmitting electrical power from a power source to the plasma region while a gas is present in the plasma region; and
c) means for applying a VHF drive voltage to said upper plasma generating electrode and RF bias voltages at a lower frequency than the VHF drive voltage to the upper and lower plasma generating electrodes.

17. The reactor of claim 16 wherein the RF bias voltages applied to said upper and lower plasma generating electrodes are out of phase with one another.

18. A method of generating a plasma for processing a workpiece comprising:
placing the workpiece in position for enabling a surface thereof to be processed;
generating a processing plasma that is at least coextensive with the surface; and
generating a boundary layer plasma surrounding the processing plasma.

19. The method of claim 18 further comprising controlling the boundary layer plasma to minimize variations in the density of the processing plasma in a direction parallel to the surface.

20. A method of performing a plasma assisted process on a workpiece, comprising:
providing first and second electrodes;
placing the workpiece between the electrodes and adjacent the second electrode, and
generating a plasma between the electrodes by applying to the first electrode a high frequency drive voltage and applying to both electrodes bias voltages at a frequency lower than that of the drive voltage.

21. The method of claim 20 wherein the bias voltage applied to the first electrode is out of phase with the bias voltage applied to the second electrode.
